(19) United States
(12) Patent Application Publication
(10) Pub. No.: US 2025/0118634 A1
(43) Pub. Date: Apr. 10, 2025

(54) INTELLIGENT POWER MODULE ARRANGEMENT

(71) Applicant: Infineon Technologies Austria AG, Villach (AT)

(72) Inventors: Chang Young PARK, Goyang-si (KR); Joon Seo SON, Seoul (KR); Stefano RUZZA, Mede (IT)

(21) Appl. No.: 18/891,101

(22) Filed: Sep. 20, 2024

(30) Foreign Application Priority Data
Oct. 6, 2023 (DE) 102023127227.6

(51) Int. Cl. H01L 23/495; H01L 23/00; H01L 23/31; H01L 23/367; H01L 25/11

(52) U.S. Cl. CPC H01L 23/4952; H01L 23/3135; H01L 23/367; H01L 24/48; H01L 24/49; H01L 25/115; H01L 2224/48137; H01L 2224/48245; H01L 2224/49109; H01L 2224/49173; H01L 2924/13055

(57) ABSTRACT

An intelligent power module includes a plurality of controllable semiconductor devices that each include a control electrode, a gate driver configured to generate one or more control signals for one or more of the plurality of controllable semiconductor devices, and one or more bridging devices that each include a housing, a plurality of contact pads arranged on an outside of the housing, and one or more electrical connections arranged inside the housing. Each of the one or more electrical connections electrically couples two of the plurality of contact pads to each other. At least one of the bridging devices is electrically coupled between the control electrodes of one or more of the plurality of controllable semiconductor devices and the gate driver, respectively, and is configured to route one or more control signals from the gate driver to the control electrodes of the one or more controllable semiconductor devices.

### CROSS-REFERENCE TO RELATED APPLICATION

This application claims priority to Germany Patent Application No. 102023127227.6 filed on Oct. 6, 2023, the content of which is incorporated by reference herein in its entirety.

### TECHNICAL FIELD

The instant disclosure relates to intelligent power module arrangements.

### BACKGROUND

Intelligent power modules may be used in rectifier, converter, and inverter stages in power management circuits and motor drives for applications like fans, hair dryers, air purifiers, and circulation pumps, for example. Intelligent power modules may comprise different components such as controllable semiconductor devices (e.g., insulated gate bipolar transistors (IGBTs) arranged in half-bridge and three-phase configurations), gate drivers, and diodes, for example. The components may be arranged in a molded package. Electrical connections inside the package may be implemented using bonding wires. Such internal wire connections should generally be thin while, at the same time, being as short as possible. Overall, the package dimensions should be small and thermal resistance should be low.

Hence, there is a general need for an intelligent power module in which internal electrical connections between different components may be formed using thin bonding wires that do not exceed a defined maximum length.

### SUMMARY

An intelligent power module includes a plurality of controllable semiconductor devices, each of the plurality of controllable semiconductor devices including a control electrode and a controllable load path between a first load electrode and a second load electrode, a gate driver configured to generate one or more control signals for one or more of the plurality of controllable semiconductor devices, and one or more bridging devices, each of the one or more bridging devices including a housing, a plurality of contact pads arranged on an outside of the housing, and one or more electrical connections arranged inside the housing, wherein each of the one or more electrical connections electrically couples two of the plurality of contact pads to each other, wherein at least one of the one or more bridging devices is electrically coupled between the control electrodes of one or more of the plurality of controllable semiconductor devices and the gate driver, respectively, and is configured to route one or more control signals from the gate driver to the control electrodes of the respective one or more controllable semiconductor devices.

A bridging device for an intelligent power module is disclosed, wherein the bridging device includes a housing, a plurality of contact pads arranged on an outside of the housing, and one or more electrical connections arranged inside the housing, wherein each of the one or more electrical connections electrically couples two of the plurality of contact pads to each other, and the bridging device is configured to be electrically coupled between the control electrodes of one or more of a plurality of controllable semiconductor devices and a gate driver of the intelligent power module, respectively, and to route one or more control signals from the gate driver to the control electrodes of the respective one or more controllable semiconductor devices.

The implementation may be better understood with reference to the following drawings and the description. The components in the figures are not necessarily to scale, emphasis instead being placed upon illustrating the principles of the implementation. In the figures, like referenced numerals designate corresponding parts throughout the different views.

### BRIEF DESCRIPTION OF THE DRAWINGS

FIG. 1 is a cross-sectional view of an intelligent power module.

FIG. 2 is a cross-sectional view of another intelligent power module.

FIG. 3 is a circuit diagram of a three-phase half-bridge arrangement.

FIG. 4 is a top view of an intelligent power module according to implementations of the disclosure.

FIG. 5 is a circuit diagram of a three-phase half-bridge arrangement according to implementations of the disclosure.

FIG. 6 is a top view of another intelligent power module according to implementations of the disclosure.

FIG. 7 schematically illustrates a top view of a bridging device according to implementations of the disclosure.

### DETAILED DESCRIPTION

In the following detailed description, reference is made to the accompanying drawings. The drawings show specific examples in which the implementation may be practiced. It is to be understood that the features and principles described with respect to the various examples may be combined with each other, unless specifically noted otherwise. As well as in the claims, designations of certain elements as “first element”, “second element”, “third element” etc. are not to be understood as enumerative. Instead, such designations serve solely to address different “elements”. That is, e.g., the existence of a “third element” does not require the existence of a “first element” and a “second element”. An electrical line as described herein may be a single electrically conductive element, or include at least two individual electrically conductive elements connected in parallel. Electrical lines may include metal and/or semiconductor material, and may be permanently electrically conductive (e.g., non-switchable). An electrical line may have an electrical resistivity that is independent from the direction of a current flowing through it. A semiconductor component (semiconductor body) as described herein may be made of (doped) semiconductor material and may be a semiconductor chip or be included in a semiconductor chip. A semiconductor body has electrically connecting pads and includes at least one semiconductor element with electrodes. The pads are electrically connected to the electrodes which includes that the pads are the electrodes and vice versa.

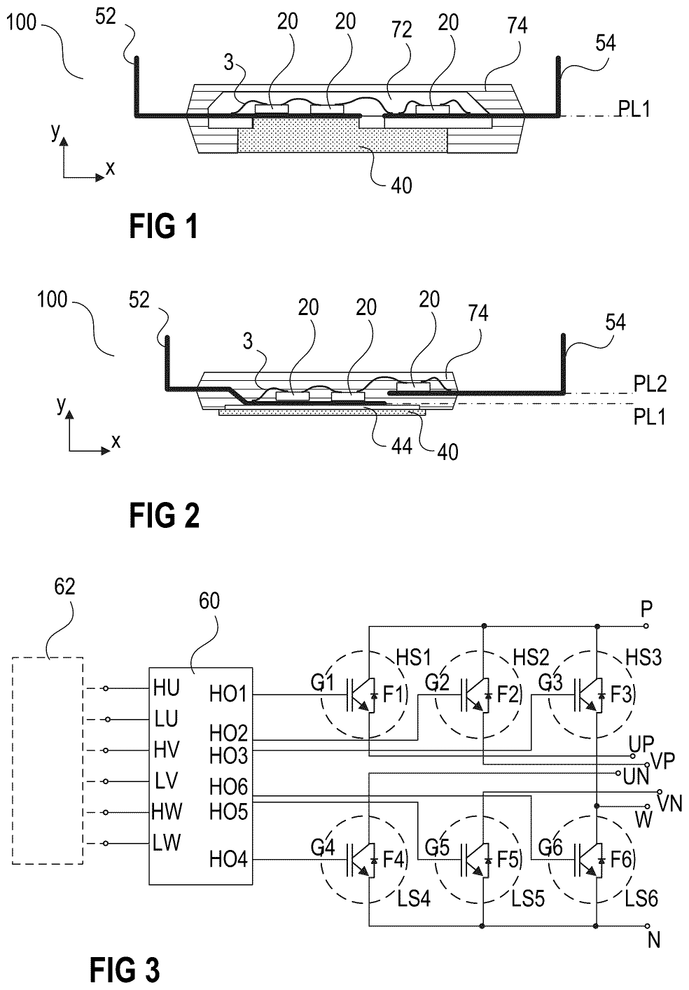

Referring to FIG. 1, an intelligent power module according to one example is schematically illustrated. An intelligent power module generally comprises one or more components 20 such as power switching devices (e.g., one or more insulated gate bipolar transistors, IGBTs) as well as additional control and protection circuitry (e.g., microcontroller, gate driver integrated circuit (IC), etc.). In other words, an intelligent power module usually comprises intelligent driving components as well as power switching components. The different components 20 are arranged in a package and electrical connections between the components 20 and an outside of the package are provided using a plurality of lead frames 52, 54. Each lead frame 52, 54 generally provides a flat mounting area arranged inside the housing. None, one or more components 20 may be arranged on different ones of the plurality of flat mounting areas inside the package. An end of the lead frames 52, 54 opposite the flat mounting area and extending to the outside of the package may be angled with respect to the flat mounting area, as is exemplarily illustrated in FIG. 1. In this way, it may be easier to contact the ends of the lead frames 52, 54.

In the intelligent power module 100 illustrated in FIG. 1, all of the flat mounting areas provided by the lead frames 52, 54 are arranged in the same plane (e.g., first plane PL1). The intelligent power module 100 further comprises a heat sink 40. The heat sink 40 may also be referred to as heat spreader, for example. The heat sink 40 may extend from one or more of the lead frames 52 towards an outside of the package. That is, at least one surface of the heat sink 40 facing away from the lead frames 52, 54 is not covered by the material forming the package. In this way, heat generated by the components 20 may be effectively dissipated away from the components 20 via the heat sink 40 to an outside of the package. However, usually not all of a plurality of lead frames 52, 54 of an intelligent power module 100 are coupled to the same electrical potential. Therefore, a heat sink 40, which often comprises or consists of a thermally as well as electrically conducting material (e.g., a metal), may directly contact some of the lead frames 52 coupled to a first potential, while being dielectrically insulated from other lead frames 54 of the intelligent power module 100 coupled to other potentials than the first potential.

This is schematically illustrated in FIG. 1. In this example, the package is formed by a first encapsulation material 72, which encapsulates the components 20 as well as a surface of the lead frames 52, 54 on which the components 20 are mounted. The first encapsulation material 72 may further be arranged between the heat sink 40 and any lead frames 54 that are not to be directly contacted by the heat sink 40, for example. A second encapsulation material 74 may encapsulate the first encapsulation material 72 and may partly encapsulate the heat sink 40. At least a surface of the heat sink 40 facing away from the lead frames 52, 54, however, is not covered by the second encapsulation material 74. The first encapsulation material 72 may be the same as or may differ from the second encapsulation material 74.

The different components 20 of an intelligent power module 100 may be mechanically and electrically coupled to respective ones of the lead frames 52, 54 using electrically conducting connection layers (not specifically illustrated). An electrically conducting connection layer may be a solder layer, a layer of an (electrically conductive) adhesive, or a layer of a sintered metal powder, e.g., a sintered silver powder, for example. The components 20 may be further electrically coupled to other components 20 or other lead frames using electrical connections 3 such as, e.g., bonding wires, or bonding ribbons.

The size of intelligent power modules 100 is generally an issue. The different components 20 arranged on the lead frames 52, 54 as well as the electrical connections 3 required to form the necessary electrical interconnections within the intelligent power module 100 require a certain amount of space. The fact that sufficient dielectric isolation is to be provided between lead frames 52, 54 and components that are coupled to different electrical potentials further adds to this problem. Now referring to FIG. 2, another example intelligent power module 100 is schematically illustrated. In this intelligent power module 100, a first subset of a plurality of lead frames 52, 54 (e.g., the flat mounting areas of the lead frames of a first subset) is arranged in the first plane PL1, while a second subset of the plurality of lead frames 52, 54 (e.g., the flat mounting areas of the lead frames of a second subset) is arranged in a second plane PL2 that is different from the first plane PL1. The lead frames 52 arranged in the first plane PL1 adjoin the heat sink 40, while the lead frames 54 arranged in the second plane PL2 are arranged distant from the heat sink 40. A layer of the encapsulation material 72 forming the package may be arranged between the heat sink 40 and the lead frames 54 of the second subset to provide sufficient dielectric insulation. Arranging different lead frames and, therefore, different components 20 in different planes PL1, PL2 allows a more compact layout of the intelligent power module 100.

Usually, those components 20 that produce a significant amount of heat during operation of the intelligent power module 100 are arranged on lead frames directly adjoining the heat sink 40. Other components 20 that do not produce a significant amount of heat during operation of the intelligent power module 100 may be arranged on lead frames of the second subset 54 arranged further away from the heat sink 40, as heat dissipation is usually not critical with respect to those components 20. Components that produce a significant amount of heat during operation of the intelligent power module 100 are usually components performing switching operations, e.g., power switching devices such as insulated gate bipolar transistors, IGBTs, for example. Components 20 included in the control and protection circuitry (e.g., microcontroller, gate driver IC, etc.) usually remain comparably cool even during operation of the intelligent power module 100.

By arranging different lead frames 52, 54 in different planes PL1, PL2 within the package 72, the overall size of the intelligent power module 100 may be decreased as compared to the arrangement as illustrated in FIG. 1 in which all lead frames 52, 54 are arranged in the same plane PL1. However, due to this additional “step” between lead frames, a length of certain electrical connections 3 (e.g., bonding wires) may increase in order to provide electrical interconnections between components 20 arranged in different planes PL1, PL2. When the length of a bonding wire increases, this usually often also requires an increased diameter of the bonding wire as compared to bonding wires having shorter lengths. In general, it is desirable to keep the length of a single electrical connection 3 (e.g., a single bonding wire) shorter than a defined maximum length, while still keeping its diameter comparably thin. For example, a single electrical connection 3 may have a length of 4.0 mm (millimeters) or less. This may be difficult to achieve in an intelligent power module 100 as is schematically illustrated in FIG. 2, for example. In FIGS. 1 and 2, molded packages are schematically illustrated. It is, however, also possible to arrange the components 20 in any other suitable kind of package instead.

The components 20 of an intelligent power module 100 may be arranged to form a half-bridge, H-bridge, or three-phase half-bridge arrangement, for example. Any other arrangements, however, are generally also possible. Now referring to FIG. 3, a circuit diagram of a three-phase half-bridge arrangement is exemplarily illustrated. The three-phase half-bridge arrangement comprises three high-side switches HS1, HS2, HS3 as well as three low-side switches LS4, LS5, LS6. Each of the high-side witches HS1, HS2, HS3 and each of the low-side switches LS4, LS5, LS6 may be implemented using one or more controllable semiconductor devices such as insulated gate bipolar transistors, IGBTs, for example. Each of the plurality of controllable semiconductor devices HS1, HS2, HS3, LS4, LS5, LS6 comprises a control electrode G1, G2, G3, G4, G5, G6 and a controllable load path between a first load electrode and a second load electrode. The load paths of the controllable semiconductor devices HS1, HS2, HS3 forming the high-side switches are coupled between a first terminal P (e.g., first terminal P coupled to a positive potential) and a respective load terminal UP, VP, W. The load paths of the controllable semiconductor devices LS4, LS5, LS6 forming the low-side switches are coupled between respective load terminals UN, VN, W and a second terminal N (e.g., second terminal coupled to negative potential).

The control electrodes G1, G2, G3, G4, G5, G6 of the controllable semiconductor devices HS1, HS2, HS3, LS4, LS5, LS6 are coupled to respective outputs HO1, HO2, HO3, HO4, HO5, HO6 of a gate driver 60. The gate driver 60, at its outputs HO1, HO2, HO3, HO4, HO5, HO6 provides respective control (gate driving) signals for the controllable semiconductor devices HS1, HS2, HS3, LS4, LS5, LS6. The gate driver 60 may receive respective inputs HU, LU, HV, LV, HW, LW from a microcontroller 62, for example, according to which it generates the control (gate driving) signals. A microcontroller 62 may be integrated in the intelligent power module 100, or may be an external device coupled to the intelligent power module 100, for example. As the microcontroller 62 is not necessarily included in the intelligent power module 100, it is indicated in dashed lines in FIG. 3.

As can be seen in FIG. 3, each of the control electrodes G1, G2, G3, G4, G5, G6 of the controllable semiconductor devices HS1, HS2, HS3, LS4, LS5, LS6 is directly coupled to the gate driver 60 in conventional intelligent power modules. As has been described above, a gate driver 60 may be arranged on a lead frame 54 arranged in a second plane PL2, while the controllable semiconductor devices HS1, HS2, HS3, LS4, LS5, LS6 may be arranged on lead frames 52 arranged in the first plane PL1 and, therefore, closer to a heat sink 40. Due to design and space restrictions, it is not always possible to arrange all of the controllable semiconductor devices HS1, HS2, HS3, LS4, LS5, LS6 in close proximity to the gate driver 60. At least some of the electrical connections 3 formed between the gate driver 60 and the controllable semiconductor devices HS1, HS2, HS3, LS4, LS5, LS6, therefore, may be required to be formed having a significant length. As has been described above, this may not be desirable.

In order to keep a length of each of the required electrical connections 3 below a defined maximum length, an intelligent power module 100 according to implementations of the disclosure comprises a plurality of controllable semiconductor devices HS1, HS2, HS3, LS4, LS5, LS6, each of the plurality of controllable semiconductor devices HS1, HS2, HS3, LS4, LS5, LS6 comprising a control electrode G and a controllable load path between a first load electrode and a second load electrode. The intelligent power module 100 further comprises a gate driver 60 configured to generate one or more control signals for one or more of the plurality of controllable semiconductor devices HS1, HS2, HS3, LS4, LS5, LS6, and one or more bridging devices 64, each of the one or more bridging devices 64 comprising a housing 642, a plurality of contact pads 644ₓ arranged on an outside of the housing 642, and one or more electrical connections 646_{y} arranged inside the housing 642, wherein each of the one or more electrical connections 646_{y} electrically couples two of the plurality of contact pads 644ₓ to each other. At least one of the one or more bridging devices 64 is electrically coupled between the control electrodes G of one or more of the plurality of controllable semiconductor devices HS1, HS2, HS3, LS4, LS5, LS6 and the gate driver 60, respectively, and is configured to route one or more control signals from the gate driver 60 to the control electrodes G of the respective one or more controllable semiconductor devices HS1, HS2, HS3, LS4, LS5, LS6.

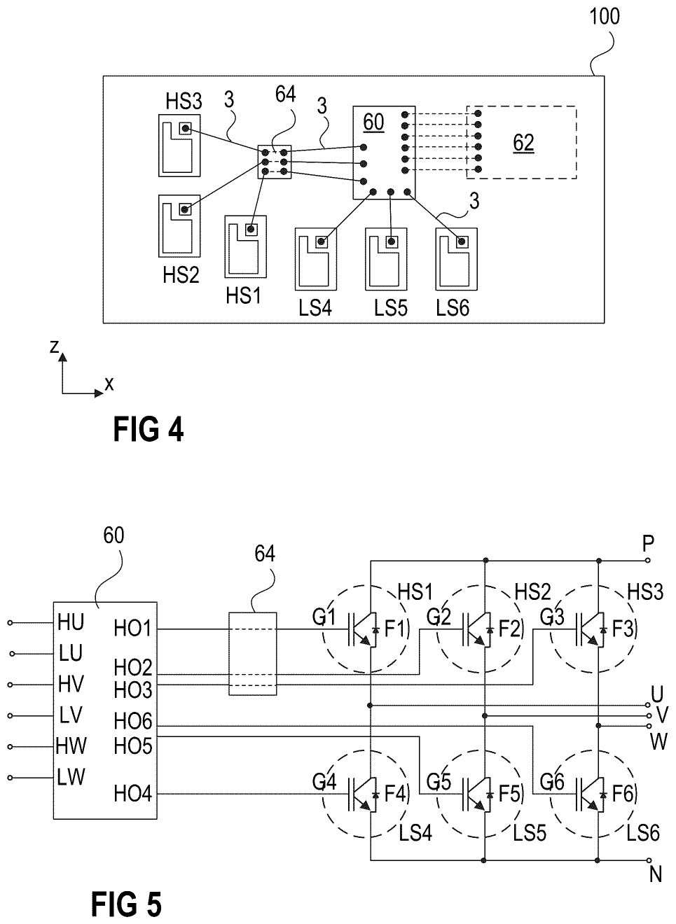

This is schematically illustrated in FIGS. 4 and 5, wherein FIG. 4 is a top view of an intelligent power module 100 according to implementations of the disclosure, and FIG. 5 is a circuit diagram of a three-phase half-bridge arrangement according to implementations of the disclosure. Arranging the controllable semiconductor devices HS1, HS2, HS3, LS4, LS5, LS6 in a three-phase half-bridge arrangement, however, is only an example. The general principles concerning the one or more bridging devices 64 similarly apply to any other arrangements as well. The bridging device 64 as illustrated in FIGS. 4 and 5 generally is a very simple component. As is schematically illustrated in FIG. 7, for example, a bridging device 64 merely provides a plurality of contact pads 644ₓ arranged on an outside of a housing 642, and one or more electrical connections 646_{y} arranged inside the housing 642, wherein each of the one or more electrical connections 646_{y} electrically couples two of the plurality of contact pads 644ₓ to each other. The electrical connections 646_{y} may be formed by simple conducting paths.

For example, each of the one or more bridging devices 64 may comprise a metallization layer arranged inside the housing 642. The metallization layer may comprise one or more sections that are separate and distinct from each other, and each of the one or more electrical connections 646_{y} may be formed by one of the one or more sections of the metallization layer. The contact pads 644ₓ may be segments of the metallization layer arranged outside of the housing 642. That is, any two contact pads 644ₓ connected to each other using an electrical connection 646_{y} may be integrally formed with the respective electrical connection 646_{y}. It is, however, also possible that the contact pads 644ₓ be formed separately and are electrically connected to the respective electrical connection 646_{y} in any suitable way. A very simple bridging device 62 may comprise only two contact pads 644₁, 644₆ that are coupled to each other using a metallization layer having only a single section 646₁. Generally, a bridging device 64, however, may comprise more than two contact pads 644ₓ, as is schematically illustrated in FIG. 7.

Different electrical connections 646_{y} of a bridging device 64 may not intersect with each other, as is schematically illustrated on the left side in FIG. 7. This may be easily implemented using a single structured metallization layer. In order to avoid intersecting bonding wires 3 leading to or from the bridging device 64, however, a bridging device 64 may be provided that provides internally intersecting electrical connections 646_{y}. This is schematically illustrated on the right side of FIG. 7. Intersecting electrical connections 646_{y} may be implemented using two or more metallization layers, for example. That is, a bridging device 64 may comprise two or more metallization layers, and one or more dielectric insulation layers arranged inside the housing 642. Each of the one or more dielectric insulation layers may be arranged between two of the two or more metallization layers such that the two or more metallization layers and the one or more dielectric insulation layers are arranged in an alternating manner. Each of the two or more metallization layers comprises one or more sections that are separate and distinct from each other. At least one of the one or more electrical connections 646_{y} may be formed by at least two different sections of at least two different metallization layers, and at least one via extending through at least one of the dielectric insulation layers and electrically coupling the respective sections. That is, a section of the first metallization layer extending in a first plane may intersect with a section of the second metallization layer extending in a second plane and may be electrically insulated from the respective section of the first metallization layer using a dielectric insulation layer.

The one or more metallization layers may be deposited on a semiconductor body, for example. The semiconductor body may comprise or consist of conventional semiconductor material such as, e.g., silicon (Si). Alternatively, it is also possible to form the one or more metallization layers on a conventional printed circuit board PCB, for example. Any other implementations are generally also possible. A semiconductor body, however, usually is significantly thinner (e.g., about 280 μm) than a PCB (e.g., up to 800 μm), for example, which may make it easier to integrate a thin semiconductor body in a package 642. PCBs having a significantly decreased thickness (e.g., below 500 μm) exist, but are generally very expensive.

Referring to FIG. 5, each of the one or more control signals generated by the gate driver 60 may be provided at a different output HO1, HO2, HO3, HO4, HO5, HO6 of the gate driver 60. The control electrodes G of the different ones of the plurality of controllable semiconductor devices HS1, HS2, HS3, LS4, LS5, LS6 are coupled to different ones of the plurality of outputs HO1, HO2, HO3, HO4, HO5, HO6 of the gate driver 60 using different ones of a plurality of signal paths. At least one of the plurality of signal paths comprises two of the plurality of contact pads 644ₓ of one of the one or more bridging devices 64, the electrical connection 646_{y} electrically coupling the two contact pads 644ₓ, a bonding wire 3 extending between one of the two contact pads 644ₓ and one of the plurality of outputs HO1, HO2, HO3, HO4, HO5, HO6 of the gate driver 60, and a bonding wire 3 extending between the other one of the two contact pads 644ₓ and the control electrode G of one of the plurality of controllable semiconductor devices HS1, HS2, HS3. That is, some of the controllable semiconductor devices HS1, HS2, HS3, LS4, LS5, LS6 may be directly coupled to the gate driver 60 using a single bonding wire (e.g., controllable semiconductor devices LS4, LS5, LS6 in FIGS. 4 and 5). Other controllable semiconductor devices HS1, HS2, HS3, LS4, LS5, LS6 may be coupled to the gate driver 60 using two separate bonding wires 3 with the bridging device 64 arranged between the two bonding wires 3 and providing an electrical connection between the two bonding wires 3 (e.g., controllable semiconductor devices HS1, HS2, HS3 in FIGS. 4 and 5). In this way, one or more of the signal paths may be “bridged” using the bridging device 64, keeping a length of the individual bonding wires 3 included in the signal path short. In this way, it is also possible to use comparably thin bonding wires 3.

For example, each bonding wire 3 extending between a contact pad 644ₓ and one of the plurality of outputs HO1, HO2, HO3, HO4, HO5, HO6 of the gate driver 60 may have a length of 4.0 mm or less, and a maximum thickness of 40 μm or less. Similarly, each bonding wire 3 extending between a contact pad 644ₓ and the control electrode G of one of the plurality of controllable semiconductor devices HS1, HS2, HS3, LS4, LS5, LS6 may have a length of 4.0 mm or less, and a maximum thickness of 40 μm or less.

In some examples, all signal paths between the plurality of controllable semiconductor devices HS1, HS2, HS3, LS4, LS5, LS6 may include an electrical connection 646_{y} of the bridging device 64. That is, none of the plurality of controllable semiconductor devices HS1, HS2, HS3, LS4, LS5, LS6 may be directly coupled to the gate driver 60 using a single bonding wire 3. It is, however, also possible that a first subset (one or more) of the controllable semiconductor devices HS1, HS2, HS3 is connected to the gate driver 60 via a bridging device 64, while a second subset (one or more) of the controllable semiconductor devices LS4, LS5, LS6 is directly connected to the gate driver 60. That is, at least one of the plurality of signal paths may comprise a bonding wire 3 extending between the control electrode G of one of the plurality of controllable semiconductor devices LS4, LS5, LS6 and one of the plurality of outputs HO1, HO2, HO3, HO4, HO5, HO6 of the gate driver 60. Each bonding wire 3 extending between the control electrode G of one of the plurality of controllable semiconductor devices LS4, LS5, LS6 and one of the plurality of outputs HO1, HO2, HO3, HO4, HO5, HO6 of the gate driver 60 may have a length of 4.0 mm or less, and a maximum thickness of 40 μm or less. That is, bridging, using a bridging device 64, a signal path that can be implemented using a single comparably short bonding wire 3 may not be required.

As has been described above, an intelligent power module 100 may further comprise a microcontroller 62, wherein the microcontroller 62 is electrically coupled to the gate driver 60, e.g., the microcontroller 62 may provide respective inputs HU, LU, HV, LV, HW, LW for the gate driver 60. The optional microcontroller 62 is indicated in dashed lines in FIG. 4. In the top view of FIG. 4, the different elements of an intelligent power module 100 and electrical connections 3 between the elements are only very generically illustrated.

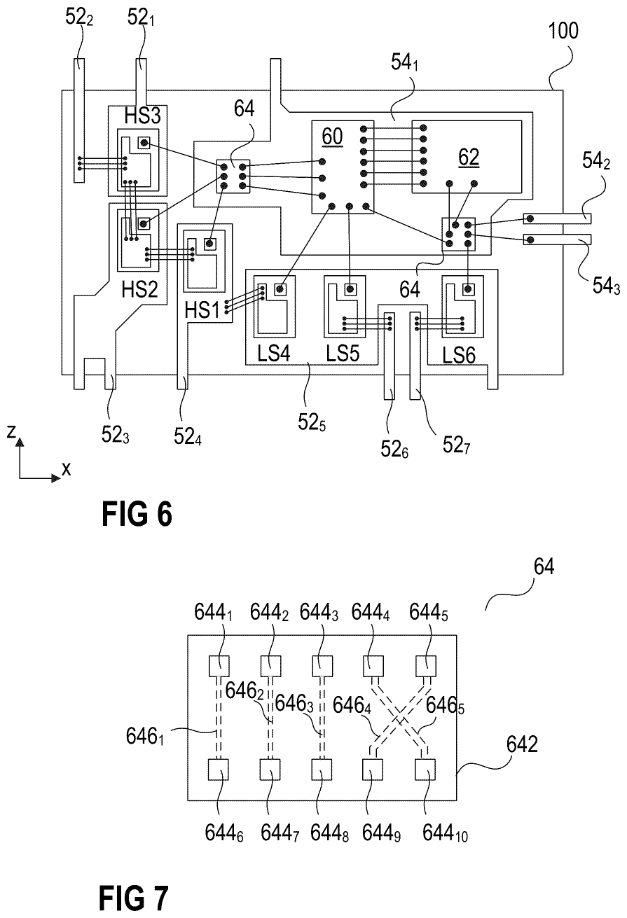

Now referring to FIG. 6, an example intelligent power module 100 is illustrated in more detail. In particular, in the top view of FIG. 6, a plurality of lead frames 52₁, 54ₘ is schematically illustrated. As can be seen, an intelligent power module 100 may comprise lead frames 52₁, 52₃, 52₄ with only one component (e.g., controllable semiconductor devices HS1, HS2, HS3) arranged thereon. An intelligent power module 100 may further comprise lead frames 52₅, 54₁ with more than one component (e.g., controllable semiconductor devices LS4, LS5, LS6 as well as gate driver 60, bridging device(s) 64, and (optional) microcontroller 62) arranged thereon. Other lead frames 52₂, 52₆, 52₇, 54₂, 54₃ may not have any components arranged thereon and may only be required to provide electrical contacts between the inside and the outside of the housing. The shape and arrangement of the different lead frames illustrated in FIG. 6 is only an example. The specific design of an intelligent power module 100 may be implemented in any other suitable way.

The intelligent power module 100 as exemplarily illustrated in FIG. 6 comprises more than one bridging device 64. In particular, the intelligent power module 100 of FIG. 6 comprises two bridging devices 64. A first one of the bridging devices 64 is arranged between the gate driver 60 and a subset of the controllable semiconductor devices HS1, HS2, HS3, similar to what has been described above. A second one of the bridging devices 64 forms a section of a signal path from the gate driver 60 to another one of the controllable semiconductor devices LS6, similar to the first bridging device 64. The second one of the bridging devices 64, however, is also electrically coupled between the microcontroller 62 and two of the lead frames 54₂, 54₃, and is configured to route one or more signals from the outside of the package to the microcontroller 62 (or vice versa). It is even possible to electrically couple a bridging device 64 between the microcontroller 62 and the gate driver 60 (not specifically illustrated), wherein the bridging device 64 is configured to route one or more signals from the microcontroller 62 to the gate driver 60. Generally, one or more bridging devices 64 may be included in an intelligent power module to route any kind of signal between any of the components included in the intelligent power module 100.

The one or more bridging devices 64 may be mechanically coupled to the respective lead frame 54₁ in any suitable way. For example, a bridging device 64 may be glued, soldered, welded, or sintered to the respective lead frame 54₁. According to one example, a bridging device 64 may be attached to the respective lead frame 54₁ using an Ag (silver) epoxy.

A bridging device 64 for an intelligent power module 100 according to implementations of the disclosure comprises a housing 642, a plurality of contact pads 644ₓ arranged on an outside of the housing 642, and one or more electrical connections 646_{y} arranged inside the housing 642. Each of the one or more electrical connections 646_{y} electrically couples two of the plurality of contact pads 644ₓ to each other, and the bridging device 64 is configured to be electrically coupled between the control electrodes G of one or more of a plurality of controllable semiconductor devices HS1, HS2, HS3, LS4, LS5, LS6 and a gate driver 60 of the intelligent power module 100, respectively, and to route one or more control signals from the gate driver 60 to the control electrodes G of the respective one or more controllable semiconductor devices HS1, HS2, HS3, LS4, LS5, LS6.

As has been described above, the bridging device 64 “bridges” a distance between the gate driver 60 and one or more controllable semiconductor devices HS1, HS2, HS3, LS4, LS5, LS6, or between any two components of an intelligent power module 100. In this way, the maximum length of the bonding wires 3 that are used to form the electrical connections between the gate driver 60 and the one or more controllable semiconductor devices HS1, HS2, HS3, LS4, LS5, LS6 (or between any two components of an intelligent power module 100) may be significantly reduced. This may be specifically advantageous in an arrangement as has been described with respect to FIG. 2 above (different lead frames arranged in different planes PL1, PL2). One or more bridging devices 64, however, may also be used in an intelligent power module 100 as has been described with respect to FIG. 1 above. As the one or more bridging devices 64 provide electrical connections 646_{y} arranged in a package 642, the bridging devices 64 can be easily handled. It is generally possible to use the same equipment to position and attach the one or more bridging devices 64 to the respective lead frame(s) as is used to position and attach the controllable semiconductor devices HS1, HS2, HS3, LS4, LS5, LS6 and/or the gate driver 60, for example. The electrical connections 646_{y} are well protected inside the package 642, therefore no specific precautions have to be taken when handling the bridging devices 64.

### ASPECTS

The following provides an overview of some Aspects of the present disclosure:

Aspect 1: An intelligent power module comprising: a plurality of controllable semiconductor devices, each controllable semiconductor device of the plurality of controllable semiconductor devices comprising a control electrode and a controllable load path between a first load electrode and a second load electrode; a gate driver configured to generate one or more control signals for one or more of the plurality of controllable semiconductor devices; and one or more bridging devices, each bridging device of the one or more bridging devices comprising a housing, a plurality of contact pads arranged on an outside of the housing, and one or more electrical connections arranged inside the housing, wherein each electrical connection of the one or more electrical connections electrically couples two contact pads of the plurality of contact pads to each other, wherein at least one bridging device of the one or more bridging devices is electrically coupled between one or more respective control electrodes of one or more controllable semiconductor devices of the plurality of controllable semiconductor devices and the gate driver, respectively, and is configured to route the one or more control signals from the gate driver to the one or more respective control electrodes of the one or more controllable semiconductor devices.

Aspect 2: The intelligent power module of Aspect 1, wherein: each control signal of the one or more control signals generated by the gate driver is provided at a different output of the gate driver, the control electrode of each controllable semiconductor device of the plurality of controllable semiconductor devices is coupled to a different one of a plurality of outputs of the gate driver using a different one of a plurality of signal paths, and at least one signal path of the plurality of signal paths comprises: two corresponding contact pads of the plurality of contact pads of a bridging device of the one or more bridging devices, an electrical connection electrically coupling the two corresponding contact pads, a first bonding wire extending between a first one of the two corresponding contact pads and one of the plurality of outputs of the gate driver, and a second bonding wire extending between a second one of the two corresponding contact pads and the control electrode of one of the plurality of controllable semiconductor devices.

Aspect 3: The intelligent power module of Aspect 2, wherein: each first bonding wire extending between a contact pad and one of the plurality of outputs of the gate driver has a length of 4.0 mm or less, and a maximum thickness of 40 μm or less; and each second bonding wire extending between a contact pad and the control electrode of one of the plurality of controllable semiconductor devices has a length of 4.0 mm or less, and a maximum thickness of 40 μm or less.

Aspect 4: The intelligent power module of Aspect 2, wherein: at least one of the plurality of signal paths comprises a third bonding wire extending between the control electrode of one of the plurality of controllable semiconductor devices and one of the plurality of outputs of the gate driver.

Aspect 5: The intelligent power module of Aspect 4, wherein: each third bonding wire extending between the control electrode of one of the plurality of controllable semiconductor devices and one of the plurality of outputs of the gate driver has a length of 4.0 mm or less, and a maximum thickness of 40 μm or less.

Aspect 6: The intelligent power module of any of Aspects 1-5, wherein: each of the one or more bridging devices comprises a metallization layer arranged inside the housing; the metallization layer comprises one or more sections that are separate and distinct from each other; and each of the one or more electrical connections is formed by one of the one or more sections of the metallization layer.

Aspect 7: The intelligent power module of Aspect 6, wherein: each of the one or more bridging devices comprises a semiconductor body arranged inside the housing, and the metallization layer is arranged on the semiconductor body.

Aspect 8: The intelligent power module of Aspect 7, wherein the semiconductor body comprises or consists of silicon.

Aspect 9: The intelligent power module of any of Aspects 1-8, wherein: each of the one or more bridging devices comprises two or more metallization layers, and one or more dielectric insulation layers arranged inside the housing, wherein each of the one or more dielectric insulation layers is arranged between two of the two or more metallization layers such that the two or more metallization layers and the one or more dielectric insulation layers are arranged in an alternating manner; each of the two or more metallization layers comprises one or more sections that are separate and distinct from each other; and at least one of the one or more electrical connections is formed by at least two different sections of at least two different metallization layers, and at least one via extending through at least one of the dielectric insulation layers and electrically coupling the respective sections.

Aspect 10: The intelligent power module of any of Aspects 1-9, wherein: the plurality of controllable semiconductor devices, the gate driver, and the one or more bridging devices are arranged in a molded package.

Aspect 11: The intelligent power module of Aspect 10, wherein: the plurality of controllable semiconductor devices are arranged in a first plane, the gate driver and the at least one bridging device are arranged in a second plane, and the first plane is arranged closer to a bottom surface of the molded package than the second plane such that, when the bottom surface of the molded package is attached to a heat sink, the plurality of controllable semiconductor devices are arranged closer to the heat sink than the gate driver and the at least one bridging device.

Aspect 12: The intelligent power module of Aspect 11, further comprising: a plurality of lead frames, each of the plurality of lead frames having a first end arranged inside the molded package, and a second end extending to the outside of the molded package.

Aspect 13: The intelligent power module of Aspect 12, wherein each of the at least one bridging device is glued, soldered, welded, or sintered to a respective one of the plurality of lead frames.

Aspect 14: The intelligent power module of Aspect 12, further comprising: a microcontroller arranged in the molded package, wherein the microcontroller is electrically coupled to the gate driver.

Aspect 15: The intelligent power module of Aspect 14, wherein at least one of the one or more bridging devices is electrically coupled between the microcontroller and the gate driver, and is configured to route one or more control signals from the microcontroller to the gate driver.

Aspect 16: The intelligent power module of Aspect 14, wherein: the microcontroller is electrically coupled to at least one of the plurality of lead frames, and at least one of the one or more bridging devices is electrically coupled between the microcontroller and one or more of the at least one of the plurality of lead frames.

Aspect 17: The intelligent power module of any of Aspects 1-16, wherein the intelligent power module comprises six controllable semiconductor devices arranged in a three-phase half-bridge arrangement.

Aspect 18: A bridging device for an intelligent power module, the bridging device comprising: a housing; a plurality of contact pads arranged on an outside of the housing; and one or more electrical connections arranged inside the housing, wherein each of the one or more electrical connections electrically couples two contact pads of the plurality of contact pads to each other, and wherein the bridging device is configured to be electrically coupled between one or more respective of one or more controllable semiconductor devices of a plurality of controllable semiconductor devices and a gate driver of the intelligent power module, respectively, and to route one or more control signals from the gate driver to the one or more respective control electrodes of the one or more controllable semiconductor devices.

Aspect 19: An intelligent power module, comprising: a first controllable semiconductor device comprising a first control electrode and a first controllable load path between a first load electrode and a second load electrode; a gate driver configured to generate a first control signal for the first controllable semiconductor device; and a first bridging device comprising a housing, a plurality of contact pads arranged on an outside of the housing, and one or more electrical connections arranged inside the housing, wherein each electrical connection of the one or more electrical connections electrically couples two respective contact pads of the plurality of contact pads to each other, wherein the bridging device is electrically coupled between the control electrode and the gate driver, and is configured to route the control signal from the gate driver to the control electrode via a first electrical connection of the one or more electrical connections.

Aspect 20: The intelligent power module of Aspect 19, further comprising: a first bonding wire extends between a first contact pad and an output of the gate driver, the first contact pad being coupled to the first electrical connection; and a second bonding wire extends between a second contact pad and the first control electrode, the second contact pad being coupled to the first electrical connection.

Aspect 21: The intelligent power module of any of Aspects 19-20, further comprising: a second controllable semiconductor device comprising a second control electrode and a second controllable load path between another first load electrode and another second load electrode, wherein the gate driver is configured to generate a second control signal for the second controllable semiconductor device, and wherein the bridging device is electrically coupled between the second control electrode and the gate driver, and is configured to route the second control signal from the gate driver to the second control electrode via a second electrical connection of the one or more electrical connections.

Aspect 22: A system configured to perform one or more operations recited in one or more of Aspects 1-21.

Aspect 23: An apparatus comprising means for performing one or more operations recited in one or more of Aspects 1-21.

1. An intelligent power module comprising:
a plurality of controllable semiconductor devices, each controllable semiconductor device of the plurality of controllable semiconductor devices comprising a control electrode and a controllable load path between a first load electrode and a second load electrode;
a gate driver configured to generate one or more control signals for one or more of the plurality of controllable semiconductor devices; and
one or more bridging devices, each bridging device of the one or more bridging devices comprising a housing, a plurality of contact pads arranged on an outside of the housing, and one or more electrical connections arranged inside the housing, wherein each electrical connection of the one or more electrical connections electrically couples two contact pads of the plurality of contact pads to each other,
wherein at least one bridging device of the one or more bridging devices is electrically coupled between one or more respective control electrodes of one or more controllable semiconductor devices of the plurality of controllable semiconductor devices and the gate driver, respectively, and is configured to route the one or more control signals from the gate driver to the one or more respective control electrodes of the one or more controllable semiconductor devices.

2. The intelligent power module of claim 1, wherein:
each control signal of the one or more control signals generated by the gate driver is provided at a different output of the gate driver,
the control electrode of each controllable semiconductor device of the plurality of controllable semiconductor devices is coupled to a different one of a plurality of outputs of the gate driver using a different one of a plurality of signal paths, and
at least one signal path of the plurality of signal paths comprises:
two corresponding contact pads of the plurality of contact pads of a bridging device of the one or more bridging devices,
an electrical connection electrically coupling the two corresponding contact pads,
a first bonding wire extending between a first one of the two corresponding contact pads and one of the plurality of outputs of the gate driver, and
a second bonding wire extending between a second one of the two corresponding contact pads and the control electrode of one of the plurality of controllable semiconductor devices.

3. The intelligent power module of claim 2, wherein:
each first bonding wire extending between a contact pad and one of the plurality of outputs of the gate driver has a length of 4.0 mm or less, and a maximum thickness of 40 μm or less; and
each second bonding wire extending between a contact pad and the control electrode of one of the plurality of controllable semiconductor devices has a length of 4.0 mm or less, and a maximum thickness of 40 μm or less.

4. The intelligent power module of claim 2, wherein:
at least one of the plurality of signal paths comprises a third bonding wire extending between the control electrode of one of the plurality of controllable semiconductor devices and one of the plurality of outputs of the gate driver.

5. The intelligent power module of claim 4, wherein:
each third bonding wire extending between the control electrode of one of the plurality of controllable semiconductor devices and one of the plurality of outputs of the gate driver has a length of 4.0 mm or less, and a maximum thickness of 40 μm or less.

6. The intelligent power module of claim 1, wherein;
each of the one or more bridging devices comprises a metallization layer arranged inside the housing;
the metallization layer comprises one or more sections that are separate and distinct from each other; and
each of the one or more electrical connections is formed by one of the one or more sections of the metallization layer.

7. The intelligent power module of claim 6, wherein:
each of the one or more bridging devices comprises a semiconductor body arranged inside the housing, and
the metallization layer is arranged on the semiconductor body.

8. The intelligent power module of claim 7, wherein the semiconductor body comprises or consists of silicon.

9. The intelligent power module of claim 1, wherein:
each of the one or more bridging devices comprises two or more metallization layers, and one or more dielectric insulation layers arranged inside the housing, wherein each of the one or more dielectric insulation layers is arranged between two of the two or more metallization layers such that the two or more metallization layers and the one or more dielectric insulation layers are arranged in an alternating manner;
each of the two or more metallization layers comprises one or more sections that are separate and distinct from each other; and
at least one of the one or more electrical connections is formed by at least two different sections of at least two different metallization layers, and at least one via extending through at least one of the dielectric insulation layers and electrically coupling the respective sections.

10. The intelligent power module of claim 1, wherein:
the plurality of controllable semiconductor devices, the gate driver, and the one or more bridging devices are arranged in a molded package.

11. The intelligent power module of claim 10, wherein:
the plurality of controllable semiconductor devices are arranged in a first plane,
the gate driver and the at least one bridging device are arranged in a second plane, and
the first plane is arranged closer to a bottom surface of the molded package than the second plane such that, when the bottom surface of the molded package is attached to a heat sink, the plurality of controllable semiconductor devices are arranged closer to the heat sink than the gate driver and the at least one bridging device.

12. The intelligent power module of claim 11, further comprising:
a plurality of lead frames, each of the plurality of lead frames having a first end arranged inside the molded package, and a second end extending to the outside of the molded package.

13. The intelligent power module of claim 12, wherein each of the at least one bridging device is glued, soldered, welded, or sintered to a respective one of the plurality of lead frames.

14. The intelligent power module of claim 12, further comprising:
a microcontroller arranged in the molded package, wherein the microcontroller is electrically coupled to the gate driver.

15. The intelligent power module of claim 14, wherein at least one of the one or more bridging devices is electrically coupled between the microcontroller and the gate driver, and is configured to route one or more control signals from the microcontroller to the gate driver.

16. The intelligent power module of claim 14, wherein:
the microcontroller is electrically coupled to at least one of the plurality of lead frames, and
at least one of the one or more bridging devices is electrically coupled between the microcontroller and one or more of the at least one of the plurality of lead frames.

17. The intelligent power module of claim 1, wherein the intelligent power module comprises six controllable semiconductor devices arranged in a three-phase half-bridge arrangement.

18. A bridging device for an intelligent power module, the bridging device comprising:
a housing;
a plurality of contact pads arranged on an outside of the housing; and
one or more electrical connections arranged inside the housing,
wherein each of the one or more electrical connections electrically couples two contact pads of the plurality of contact pads to each other, and
wherein the bridging device is configured to be electrically coupled between one or more respective of one or more controllable semiconductor devices of a plurality of controllable semiconductor devices and a gate driver of the intelligent power module, respectively, and to route one or more control signals from the gate driver to the one or more respective control electrodes of the one or more controllable semiconductor devices.

19. An intelligent power module, comprising:
a first controllable semiconductor device comprising a first control electrode and a first controllable load path between a first load electrode and a second load electrode;
a gate driver configured to generate a first control signal for the first controllable semiconductor device; and
a first bridging device comprising a housing, a plurality of contact pads arranged on an outside of the housing, and one or more electrical connections arranged inside the housing,
wherein each electrical connection of the one or more electrical connections electrically couples two respective contact pads of the plurality of contact pads to each other, and
wherein the bridging device is electrically coupled between the control electrode and the gate driver, and is configured to route the control signal from the gate driver to the control electrode via a first electrical connection of the one or more electrical connections.

20. The intelligent power module of claim 19, further comprising:
a first bonding wire extends between a first contact pad and an output of the gate driver, the first contact pad being coupled to the first electrical connection; and
a second bonding wire extends between a second contact pad and the first control electrode, the second contact pad being coupled to the first electrical connection.

21. The intelligent power module of claim 19, further comprising:
a second controllable semiconductor device comprising a second control electrode and a second controllable load path between another first load electrode and another second load electrode,
wherein the gate driver is configured to generate a second control signal for the second controllable semiconductor device, and
wherein the bridging device is electrically coupled between the second control electrode and the gate driver, and is configured to route the second control signal from the gate driver to the second control electrode via a second electrical connection of the one or more electrical connections.
